(19) United States
(12) Patent Application Publication
(10) Pub. No.: US 2013/0152991 A1
(43) Pub. Date: Jun. 20, 2013

(54) PHOTOELECTRIC MODULE

(71) Applicant: Hyun-Chul Kim, Yongin-si (KR)

(72) Inventor: Hyun-Chul Kim, Yongin-si (KR)

(21) Appl. No.: 13/425,401

(22) Filed: Mar. 20, 2012

Related U.S. Application Data
(60) Provisional application No. 61/577,245, filed on Dec. 19, 2011.

(51) Int. Cl. H01L 31/05

(52) U.S. Cl. 136/244

(57) ABSTRACT

A photoelectric conversion module includes a plurality of electrically coupled cells, each including a first substrate on which a first electrode is located, a second substrate on which a second electrode is located, and a sealing member between the first and second substrates, and first and second electrode terminals respectively extending from the first and second electrodes to beyond edges of the sealing member on opposite sides of the sealing member, wherein positions of the first and second electrode terminals of adjacent ones of the cells are respectively different.

### CROSS-REFERENCE TO RELATED APPLICATION

This application claims priority to and the benefit of U.S. Provisional Application No. 61/577,245, filed on Dec. 19, 2011 in the USPTO, the disclosure of which is incorporated herein in its entirety by reference.

### BACKGROUND

1. Field

One or more embodiments of the present invention relate to a photoelectric conversion module.

2. Description of Related Art

Extensive research has recently been conducted on photoelectric conversion devices that convert light into electric energy. From among such devices, solar cells have attracted much attention as alternative energy sources to fossil fuels.

As research on solar cells having various working principles has been conducted, wafer-based silicon or crystalline solar cells using a p-n semiconductor junction have appeared to be the most prevalent ones. However, the manufacturing costs of wafer-based crystalline silicon or solar cells are high because they are formed of a high purity semiconductor material.

Unlike silicon solar cells, dye-sensitized solar cells include a photosensitive dye that receives visible light and generates excited electrons, a semiconductor material that receives the excited electrons, and an electrolyte that reacts with electrons returning from an external circuit. Since dye-sensitized solar cells have much higher photoelectric conversion efficiency than other conventional solar cells, the dye-sensitized solar cells are viewed as the next-generation solar cells. To obtain a high photoelectromotive power, solar cells may be modularized by electrically coupling a plurality of cells. According to connection structures that electrically couple the modularized solar cells, dead areas may be formed, and a connection operation of the solar cells may be difficult to perform.

### SUMMARY

One or more embodiments of the present invention include photoelectric conversion modules, in which dead areas formed in connection structures that electrically couple a plurality of modularized cells are reduced or eliminated.

One or more embodiments of the present invention include photoelectric conversion modules in which a connection operation of electrically coupling a plurality of cells is easily performed.

According to one or more embodiments of the present invention, a photoelectric conversion module includes a plurality of electrically coupled cells, each including a first substrate on which a first electrode is located, a second substrate on which a second electrode is located, and a sealing member between the first and second substrates, and first and second electrode terminals respectively extending from the first and second electrodes to beyond edges of the sealing member on opposite sides of the sealing member, wherein positions of the first and second electrode terminals of adjacent ones of the cells are respectively different.

The first electrode terminal of a first cell of the plurality of cells and the second electrode terminal of a second cell that is adjacent to the first cell from among the plurality of cells may be on a same side with respect to the sealing member.

The photoelectric conversion module may further include a connector electrically coupling the first electrode terminal of the first cell to the second electrode terminal of the second cell.

The photoelectric conversion module may further include a plurality of connectors to respectively electrically couple different pairs of the cells.

The first electrode terminal of the first cell and the second electrode terminal of the second cell may be offset in a direction perpendicular to the substrate.

The connector may include a flexible material.

The connector may extend along an arrangement direction of the plurality of cells.

The connector may extend from between the first electrode terminal and a support of the first cell to the second electrode terminal of the second cell.

The connector may be bar-shaped or rod-shaped, and a lower end of the connector may contact the support of the first cell and the second electrode terminal of the second cell, and an upper end of the connector may contact the first electrode terminal of the first cell.

The support of the first cell may be electrically insulated from the second electrode of the first cell.

The support may include a same material as a material of the second electrode of the first cell and may be spatially separated from the second electrode.

Each of the plurality of cells may have a substantially rectangular shape, and the first and second electrode terminals of respective ones of the plurality of cells may be formed at adjacent short sides of the cells.

The first and second electrode terminals may be formed at first end portions of the first and second substrates, respectively.

The first end portions of the first and second substrates may extend beyond respective edges of the sealing member on opposite sides of the sealing member.

The first and second substrates may be coupled to face each other, and may be offset with respect to each other in a direction perpendicular to an arrangement direction of the cells, and the first end portions of the first and second substrates may be each respectively offset with respect to an opposite substrate of the first and second substrates in the direction perpendicular to the arrangement direction of the cells.

The first end portion of the second substrate may be offset from the first substrate in a direction perpendicular to an arrangement direction of the cells.

The second substrate may further include a second end portion on a side of the second substrate that is opposite to the first end portion of the second substrate, and a support of the second substrate may be electrically insulated from the second electrode of the second substrate and may be located on the second end portion of the second substrate.

The second substrate may be longer than the first substrate.

The photoelectric conversion module may further include an electrolyte-filled space enclosed by the first and second substrates and the sealing member.

The first electrode terminal may be integrally formed with the first electrode, and the second electrode terminal may be integrally formed with the second electrode.

According to the embodiments of the present invention, dead areas, which are formed in connection structures for electrically coupling a plurality of modularized cells, are reduced or eliminated. In addition, a connection operation of electrically coupling a plurality of cells may be easily performed.

### BRIEF DESCRIPTION OF THE DRAWINGS

FIG. 1 is a perspective view of a photoelectric conversion module according to an embodiment of the present invention;

FIG. 2 is a disassembled perspective view of a cell of the photoelectric conversion module of the embodiment shown in FIG. 1;

FIG. 3 is a cross-sectional view illustrating the cell of the embodiment shown in FIG. 2, cut along a line III-III;

FIG. 4 is a perspective view of a photoelectric conversion module according to another embodiment of the present invention;

FIG. 5 is a disassembled perspective view of a cell of the photoelectric conversion module of the embodiment shown in FIG. 4;

FIG. 6 is a perspective view illustrating a connection structure of adjacent cells in the photoelectric conversion module of the embodiment shown in FIG. 4; and

FIG. 7 is a cross-sectional view of the cell of the embodiment shown in FIG. 5 cut along a line VII-VII.

### DETAILED DESCRIPTION

Hereinafter, embodiments of the present invention will be described with reference to the attached drawings.

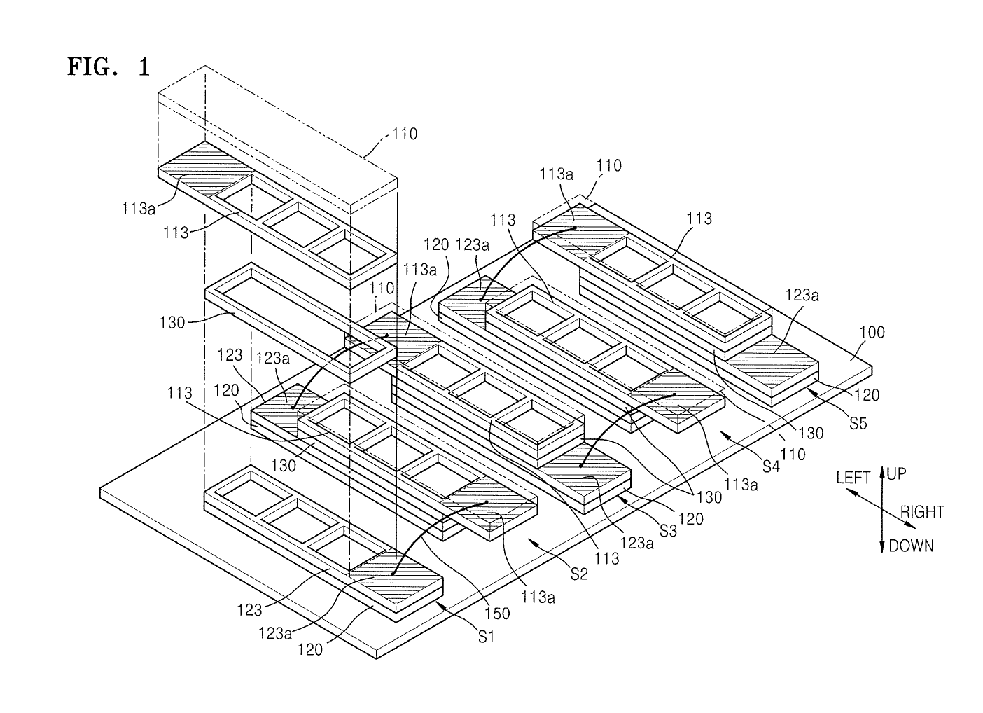

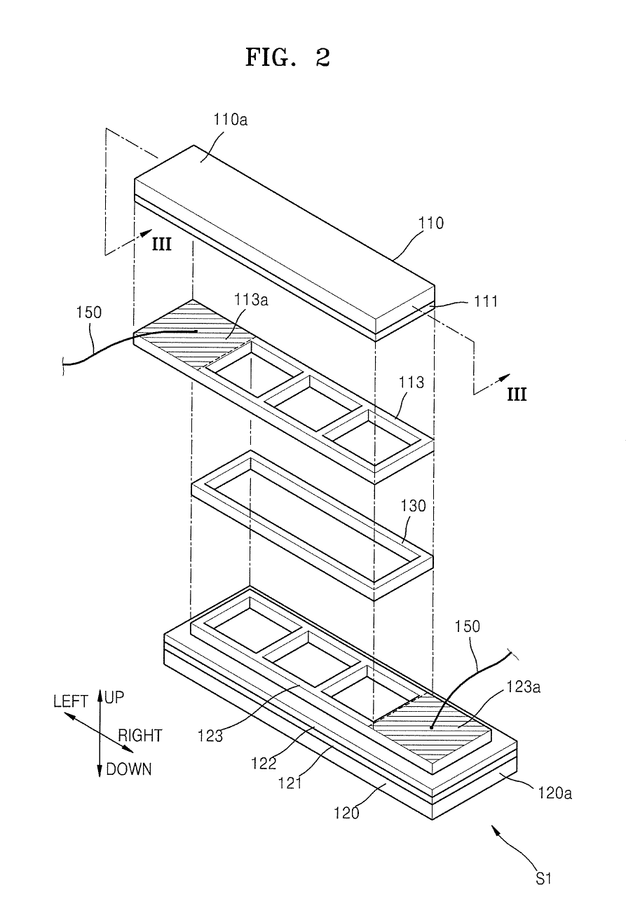

FIG. 1 is a perspective view of a photoelectric conversion module according to an embodiment of the present invention. FIG. 2 is a disassembled perspective view of a cell S1 of the photoelectric conversion module of the embodiment shown in FIG. 1.

Referring to FIGS. 1 and 2, the photoelectric conversion module of the present embodiment includes at least two cells (e.g., a plurality of cells), such as, for example, cells S1, S2, S3, S4, and S5, and a group of the cells S1, S2, S3, S4, and S5 may be electrically coupled in series or in parallel in a module. For example, a group of the cells S1, S2, S3, S4, and S5 may be arranged in rows on a support substrate 100 and may be electrically coupled to one another via one or more connectors (e.g., one or more connection members) 150. For example, the group of the cells S1, S2, S3, S4, and S5 may be electrically coupled serially as first electrodes 113 and second electrodes 123 of respective adjacent cells S1, S2, S3, S4, and S5 are electrically coupled to each other.

Referring to FIG. 2, one of the cells S1, S2, S3, S4, and S5 forming the photoelectric conversion module of the present embodiment (for example, the cell S1) is illustrated. Although only the first cell S1 is illustrated in FIG. 2, the other cells S2, S3, S4, and S5 may have substantially the same structure, and thus, a description of S1 also applies to the cells S2, S3, S4, and S5.

The first cell S1 includes a first substrate 110 on which the first electrode 113 is formed and a second substrate 120 on which the second electrode 123 is formed. The first substrate 110 and the second substrate 120 are shown arranged in a vertical direction, and may be coupled to face each other with a sealing member 130 therebetween. The first and second electrodes 113 and 123 may include first and second electrode terminals 113a and 123a respectively extending from the first and second electrodes 113 and 123 in opposite directions (e.g., in left and right directions). In the present embodiment, the first and second electrode terminals 113a and 123a extending from the first and second electrodes 113 and 123 indicates that the first and second electrode terminals 113a and 123a are electrically coupled to the first and second electrodes 113 and 123.

The first and second substrates 110 and 120 are coupled to face each other with the sealing member 130 therebetween, and an electrolyte may be filled in space (e.g., a volume, an area, or areas) formed by coupling the first and second substrates 110 and 120 with the sealing member 130 therebetween. An inner area surrounded by the sealing member 130 may be used as a photoelectric conversion unit that absorbs incident light to generate a photocurrent.

The first and second electrode terminals 113a and 123a are formed on sides (e.g., left and right sides) of the sealing member 130, respectively. For example, the first and second electrode terminals 113a and 123a may be formed on opposite sides in a length direction (left-right direction). For example, when assuming that the cell S1 has a substantially rectangular shape including a pair of long side portions and a pair of short side portions, the first and second electrode terminals 113a and 123a may be formed as the short side portions of the cell S1.

The first and second electrode terminals 113a and 123a are formed to electrically couple the structurally individualized cells S1, S2, S3, S4, and S5. In detail, a first electrode terminal 113a of a cell and a second electrode terminal 123a of another cell that is adjacent to the cell are electrically coupled to each other such that a group of the cells forms a photoelectric conversion module. For example, the first and second electrode terminals 113a and 123a may electrically couple the cells S1, S2, S3, S4, and S5 via the connector(s) 150 extending in a direction of arrangement of the cells S1, S2, S3, S4, and S5.

The first and second electrode terminals 113a and 123a may respectively be a single unit with the first and second electrodes 113 and 123 (e.g., the first electrode terminal 113a may be integrally formed with the first electrode 113, and the second electrode terminal 123a may be integrally formed with the second electrode 123), and the first and second electrode terminals 113a and 123a may extend from the first and second electrodes 113 and 123 to the outside of the sealing member 130 (e.g., beyond the edges of the sealing member 130). For example, the first electrode 113 may be formed on the first substrate 110, which is a light-receiving surface, and the first electrode 113 may be used as a negative electrode that withdraws excitation electrons generated by light. Thus, the first electrode terminal 113a that extends from the first electrode 113 may form a negative electrode terminal.

The second electrode 123 may be formed on the second substrate 120 that is opposite to the light-receiving surface, and may be used as a positive electrode that receives a current flow that has passed through an external circuit. Thus, the second electrode terminal 123a extending from the second electrode 123 may form a positive electrode terminal.

In the group of the cells S1, S2, S3, S4, and S5 forming the photoelectric conversion module, the first and second electrode terminals 113a and 123a of adjacent ones of the cells S1, S2, S3, S4, and S5, that is, for example, adjacent ones of the first and second electrode terminals 113a and 123a having opposite polarities, may be electrically coupled to each other to form a serial connection, and a high output photo-electromotive power may be obtained.

The first and second electrode terminals 113a and 123a are formed on end portions 110a and 120a of the first and second substrates 110 and 120, respectively. For example, the end portions 110a and 120a of the first and second substrates 110 and 120, on which the first and second electrode terminals 113a and 123a are respectively formed, respectively extend from the first and second substrates 110 and 120 that face each other by being offset from the opposite first and second substrates 110 and 120. For example, the end portion 110a of the first substrate 110, on which the first electrode terminal 113a is formed, and/or the end portion 120a of the second substrate 120, on which the second electrode terminal 123a is formed, may respectively extend offset from the second substrate 120 and/or the first substrate 110 that is opposite thereto.

Referring to FIG. 2, the end portion 110a of the first substrate 110, on which the first electrode terminal 113a is formed on the left of the sealing member 130, extends offset from the second substrate 120. Also, the end portion 120a of the second substrate 120, on which the second electrode terminal 123a is formed on the right of the sealing member 130, extends offset from the first substrate 110.

For example, the first and second substrates 110 and 120 may be coupled to each other in an offset manner along the length direction, and the end portions 110a and 120a may extend offset from opposite substrates, that is, the second and first substrates 120 and 110, respectively. For example, the end portion 110a of the first substrate 110 on the left of the sealing member 130 may protrude outside, or beyond, the second substrate 120, and the end portion 120 of the second substrate 120 on the right of the sealing member 130 may protrude outside, or beyond, the first substrate 110. By forming the first and second electrode terminals 113a and 123a on the end portions 110a and 120a of the first and second substrates 110 and 120, respectively, to extend offset from respective opposite substrates, physical interference may be reduced when coupling the connectors 150 to the first and second terminals 113a and 123a.

Referring to FIG. 1, the adjacent cells S1, S2, S3, S4, and S5 are arranged in reversed (e.g., alternating) patterns, where positions of the first and second electrode terminals 113a and 123a thereof alternate between left and right. For example, adjacent ones of the cells S1, S2, S3, S4, and S5 are placed on the substrate 100 at a 180 degree difference from one another.

For example, the second electrode terminal 123a of the cell S1 and the first electrode terminal 113a of the cell S2 are arranged adjacent to each other on the same side of the sealing member 130 (e.g., on the right side of the sealing member 130).

Similarly, the second electrode terminal 123a of the cell S2 and the first electrode terminal 113a of the cell S3 are arranged adjacent to each other on the same side of the sealing member 130 (e.g., on the left side of the sealing member 130).

Likewise, the second electrode terminal 123a of the cell S3 and the first electrode terminal 113a of the cell S4 are arranged adjacent to each other on the same side of the sealing member 130 (e.g., on the right side of the sealing member 130).

By arranging the cells S1, S2, S3, S4, and S5 such that the first and second electrode terminals 113a and 123a of opposite polarities are adjacently placed and electrically coupled on the left side or on the right side of the sealing member 130 (e.g., coupled to respective ones of the second and first electrode terminals 123a and 113a of respective ones of the cells S1, S2, S3, S4, and S5), the group of the cells S1, S2, S3, S4, and S5 may be serially connected. The first and second electrode terminals 113a and 123a of the adjacent cells S1, S2, S3, S4, and S5 may be electrically coupled in a serial manner via the connectors 150. The connectors 150 may be alternately formed at the left and on the right of the sealing member 130 along the arrangement direction of the cells S1, S2, S3, S4, and S5 to electrically couple the adjacent cells S1, S2, S3, S4, and S5.

The connectors 150 may be formed of various materials having electrical conductivity, and may be formed of, for example, a metal having a high conductivity, such as copper. For example, the connectors 150 may be formed of a flexible metal wire or may be formed of a hard metal.

The connectors 150 formed of metal wire may be useful in electrically coupling adjacent ones of the cells S1, S2, S3, S4, and S5, for example, in terms of facilitating welding thereof. For example, by welding a first end of the connector 150 to the first electrode terminal 113a of one of the cells S1, S2, S3, S4, and S5, and by welding a second end of the connector 150 to the second electrode terminal 123 of another adjacent one of the cells S1, S2, S3, S4, and S5, the first and second electrode terminals 113a and 123a may be electrically coupled to each other. Here, by using a flexible connector 150, welding of the first and second electrode terminals 113a and 123a may be easily performed.

The coupled first and second electrode terminals 113a and 123a are supported by the first and second substrates 110 and 120, or the end portions 110a and 120a thereof, of the adjacent cells S1, S2, S3, S4, and S5. Thus, for example, the second electrode terminal 123a formed on the second substrate 120 in a lower portion of the cell S1, and the first electrode terminal 113a formed under the first substrate 110 in an upper portion of the cell S2, may be electrically coupled diagonally via the connector 150 formed of metal wire. That is, the connector 150 may extend diagonally to couple the first and second electrode terminals 113a and 123a of the adjacent ones of the cells S1, S2, S3, S4, and S5, which are spaced apart in the vertical direction.

Referring to FIG. 1, the connector 150 electrically couples each respective pair of adjacent cells S1, S2, S3, S4, and S5, and a plurality of connectors 150 may be formed to couple different pairs of the cells S1, S2, S3, S4, and S5. According to the direction of arrangement of the cells S1, S2, S3, S4, and S5, the plurality of connectors 150 between the adjacent cells S1, S2, S3, S4, and S5 are alternately arranged on the left and right sides of the photoelectric conversion module. For example, along the direction of arrangement of the cells S1, S2, S3, S4, and S5, the connector 150 between the cell S1 and the cell S2 is formed at the right side of the photoelectric conversion module, and the connector 150 between the cell S2 and the cell S3 is formed at the left side of the photoelectric conversion module. Also, the connector 150 between the cell S3 and the cell S4 is formed at the right side of the photoelectric conversion module again, and so on.

For example, the cells S1, S2, S3, S4, and S5 that form the photoelectric conversion module may have a rectangular shape having a pair of long side portions and a pair of short side portions, and the connector 150 electrically couples the short side portions of adjacent ones of the cells S1, S2, S3, S4, and S5, that is, the first and second electrode terminals 113a and 123a formed as the short side portions of the cells S1, S2, S3, S4, and S5.

As described above, as the connector 150 electrically couples the short side portions of respective pairs of adjacent ones of the cells S1, S2, S3, S4, and S5, dead areas of the photoelectric conversion module formed due to the connection structure, that is, dead areas that do not contribute to photoelectric conversion according to reception of incident light, may be reduced or eliminated, and a light output efficiency per a unit surface area may be increased.

For example, if the first and second electrode terminals 113a and 123a are formed as the long side portions of the cells S1, S2, S3, S4, and S5, instead of as the short side portions as previously described, and the connector 150 couples the long side portions of respective ones of each of the cells, a surface area for a connection structure is increased along a length direction of the long side portions, and thus, dead areas of the photoelectric conversion module may be increased.

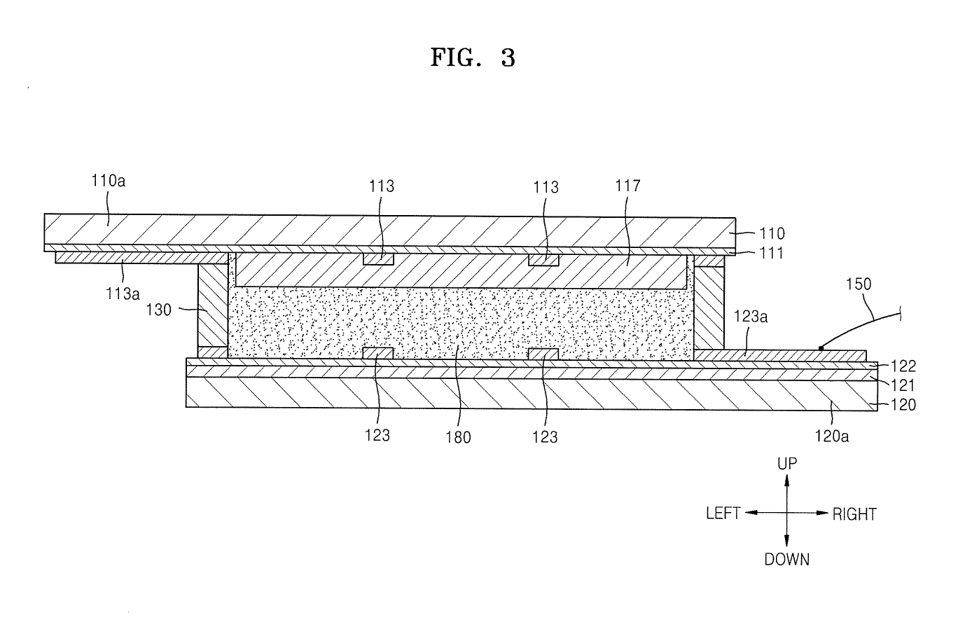

FIG. 3 is a cross-sectional view illustrating the cell S1 of the photoelectric conversion module of the embodiment shown in FIG. 2, cut along a line III-III. The components of the cell S1 are described in detail below with reference to FIG. 3.

The first and second substrates 110 and 120 may be formed of a transparent material having a high light transmitting rate. For example, the first and second substrates 110 and 120 may be formed of a glass substrate or a resin film. A resin film usually has flexibility, and thus, is appropriate for use where flexibility is required.

First and second conductive layers 111 and 121 may be formed of a transparent conductive material having electrical conductivity and optical transparency on the first and second substrates 110 and 120, respectively. For example, the first and second conductive layers 111 and 121 may be formed of a transparent conductive oxide (TCO) such as indium tin oxide (ITO), fluorinated tin oxide (FTO), or antimony tin oxide (ATO).

The first and second electrodes 113 and 123 may be formed of an opaque metal having a high electrical conductivity (e.g., aluminum (Al) or silver (Ag)) on the first and second substrates 110 and 120, respectively.

Although not shown in FIG. 3, a protection layer may be formed on surfaces of the first and second electrodes 113 and 123. The protection layer may prevent or reduce corrosion of the first and second electrodes 113 and 123, and may be formed of a material that does not react with an electrolyte 180. For example, the protection layer may be formed of a glass frit.

A light-absorbing layer 117 may be formed adjacent to the first electrode 113. For example, the light-absorbing layer 117 may be formed on the first electrode 113, and may include a semiconductor layer and a photosensitive dye that is adsorbed on the semiconductor layer. For example, the semiconductor layer may be formed of a metal oxide of Cd, Zn, In, Pb, Mo, W, Sb, Ti, Ag, Mn, Sn, Zr, Sr, Ga, Si, Cr.

For example, the photosensitive dye adsorbed in the semiconductor layer may absorb a visible light band, and may be formed of molecules that cause quick electron transfer from a light excitation state to the semiconductor layer. For example, a ruthenium-based dye may be used as the photosensitive dye.

A reduction catalyst layer 122 may be formed between the second substrate 120 and the second electrode 123. The reduction catalyst layer 122 may be formed of a material that has a reduction-catalyzing function and provides electrons to the electrolyte 180. The reduction catalyst layer 122 may be formed of a metal such as, for example, platinum (Pt), gold (Au), silver (Ag), copper (Cu), aluminum (Al), a metal oxide such as tin oxide, or a carbonaceous material such as graphite. The electrolyte 180 between the light-absorbing layer 117 and the reduction catalyst layer 122 may include a Redox electrolyte including a pair of an oxidant and a reducing agent.

The first and second electrodes 113 and 123, respectively including the first and second electrode terminals 113a and 123a extend beyond (e.g., to the outside of) the sealing member 130. For example, the first and second electrode terminals 113a and 123a, may be formed on left and right sides of the sealing member 130, respectively. After the first and second electrode terminals 113a and 123a are formed, the end portions 110a and 120a of the first and second substrates 110 and 120, on which the first and second electrode terminals 113a and 123a are formed, may respectively extend offset from the second and first substrates 110 and 120. Because the first and second electrode terminals 113a and 123a are formed on the end portions 110a and 120a of the first and second substrates 110 and 120 to respectively extend offset from opposite ones of the substrates 110 and 120, physical interference may be reduced when coupling the first and second electrode terminals 113a and 123a.

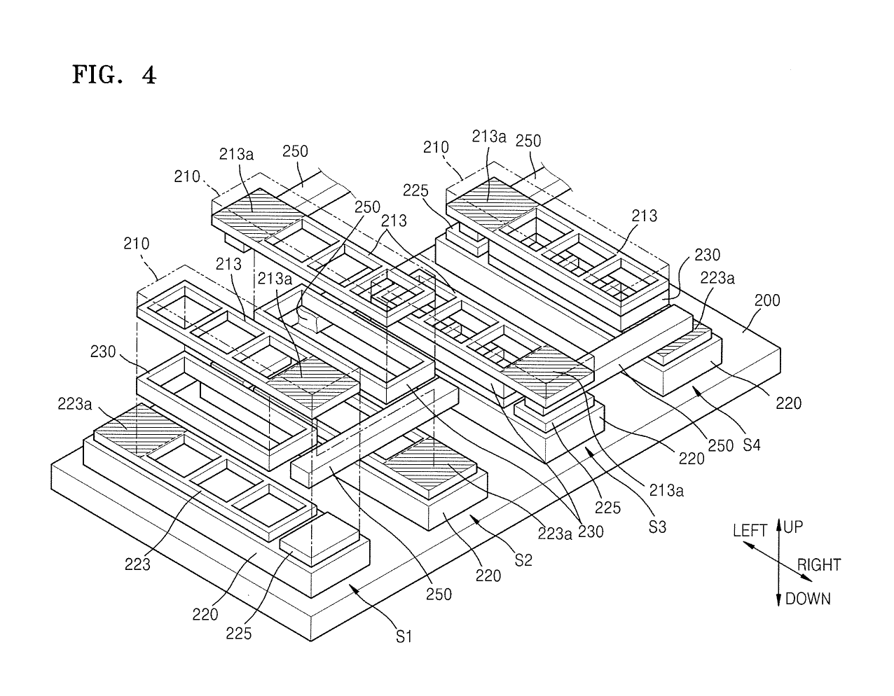

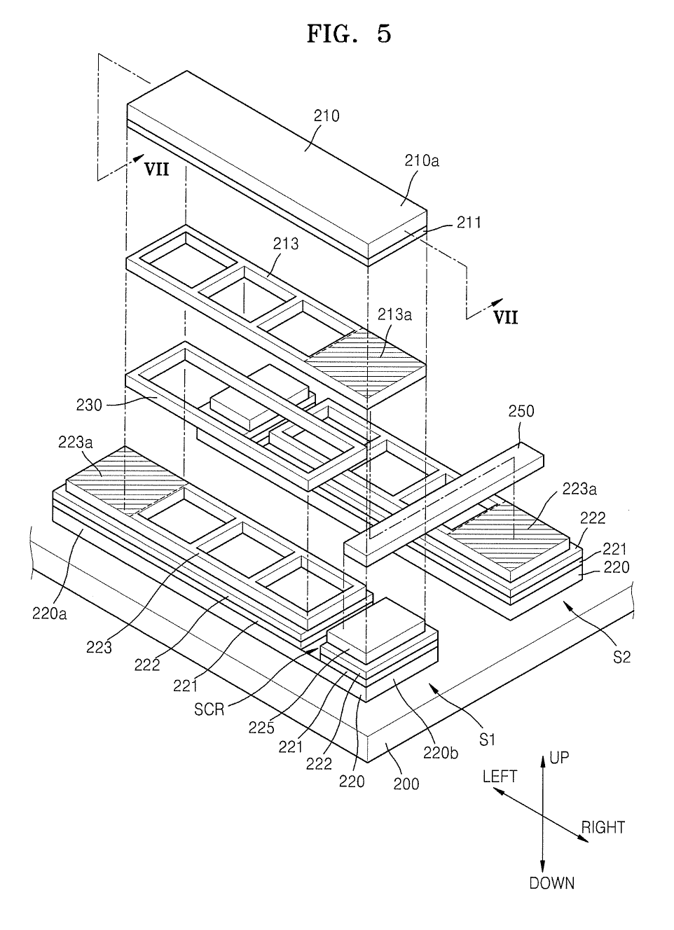

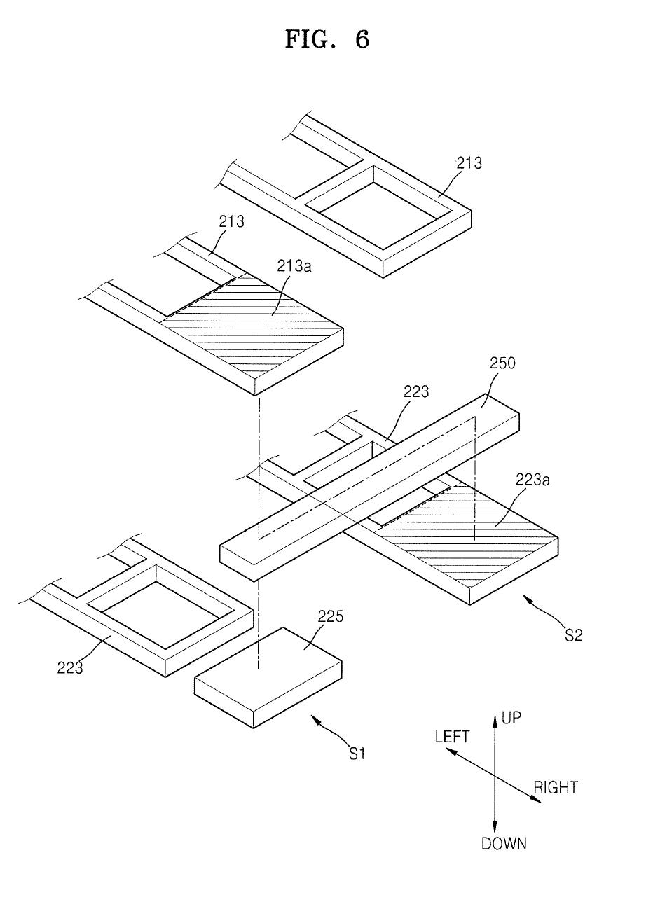

FIG. 4 is a disassembled perspective view of a photoelectric conversion module according to another embodiment of the present invention. FIG. 5 is a disassembled perspective view of a cell S1 of the photoelectric conversion module of the embodiment shown in FIG. 4. FIG. 6 is a perspective view illustrating an electrical connection structure of the cell S1 of the photoelectric conversion module of the embodiment shown in FIG. 5.

Referring to FIGS. 4 and 5, the photoelectric conversion module of the present embodiment includes a plurality of at least two cells S1, S2, S3, and S4, and a group of the cells S1, S2, S3, and S4 may be coupled in series or in parallel in a module. For example, a group of the cells S1, S2, S3, and S4 may be arranged in rows on a support substrate 200, and may be electrically coupled to one another via connectors (e.g., connection members) 250. For example, the group of the cells S1, S2, S3, and S4 may be coupled serially via first electrodes 213 and second electrodes 223 of respective adjacent ones of the cells S1, S2, S3, and S4 that are coupled to each other.

Referring to FIG. 5, one of the cells S1, S2, S3, and S4 forming the photoelectric conversion module, for example, the cell S1, is illustrated. Although only the cell S1 is illustrated in FIG. 5, the other cells S2, S3, and S4 have substantially the same structure, and thus, a description of the cell S1 substantially applies to the cells S2, S3, and S4.

The cell S1 of the photoelectric conversion module of the present embodiment includes a first substrate 210 on which the first electrode 213 is formed and a second substrate 220 on which the second electrode 223 is formed, and the first and second substrates 210 and 220 may be coupled to face each other with a sealing member 230 therebetween. The first and second electrodes 213 and 223 may include first and second electrode terminals 213a and 223a, respectively, extending outside of the sealing member 230 in opposite (e.g., left and right) directions. In the present embodiment, the first and second electrode terminals 213a and 223a extending from the first and second electrodes 213 and 223 indicate that the first and second electrode terminals 213a and 223a are electrically coupled to the first and second electrodes 213 and 223, respectively.

The first and second substrates 210 and 220 are coupled to face each other with the sealing member 230 therebetween, and an electrolyte (not shown) may be filled in a space (e.g., a volume(s), or area(s)) formed by coupling the first and second substrates 210 and 220 with the sealing member 230 therebetween. An inner area surrounded by the sealing member 230 may be used as a photoelectric conversion unit that absorbs incident light to generate a photocurrent.

The first and second electrode terminals 213a and 223a are formed on left and right sides of the sealing member 230, respectively. For example, the first and second electrode terminals 213a and 223a may be formed on opposite sides in a length direction (e.g., in a left-right direction). The first and second electrode terminals 213a and 223a are respectively electrically coupled to the first and second electrodes 213 and 223 and may respectively have the same polarities as those of the first and second electrodes 213 and 223.

In detail, the first electrode terminal 213a may extend from the first electrode 213, which is a light negative electrode, and may form a negative electrode terminal for withdrawing excitation electrons generated by light. The second electrode terminal 223a may extend from the second electrode 223, which is an opposite electrode, to form a positive electrode terminal that receives a current flow that has passed through an external circuit.

By coupling the first and second electrode terminals 213a and 223a having opposite polarities between respective pairs of adjacent ones of the cells S1, S2, S3, and S4, a photoelectric conversion module, in which a group of the cells S1, S2, S3, and S4 are serially coupled, may be formed, and a high output photoelectromotive power may be obtained according to the number of cells S1, S2, S3, and S4. Here, the first and second electrode terminals 213a and 223a of the adjacent cells S1, S2, S3, and S4 may be coupled to each other via the connector 250.

The first and second electrode terminals 213a and 223a may be a single unit with the first and second electrodes 213 and 223 (e.g., the first and second electrode terminals 213a and 223a may be integrally formed with the first and second electrodes 213 and 223, respectively) and may extend from the first and second electrodes 213 and 223. However, as long as the first and second electrode terminals 213a and 223a are electrically coupled to the first and second electrodes 213 and 223, respectively, a connection structure of the first and second electrode terminals 213a and 223a and the first and second electrodes 213 and 223 is not limited.

The first and second electrode terminals 213a and 223a are formed on end portions 210a and 220a of the first and second substrates 210 and 220, respectively. The end portions 210a and 220a of the first and second substrates 210 and 220, on which the first and second electrode terminals 213a and 223a are formed, respectively, extend offset from respective opposite substrates. Referring to the embodiment of FIG. 5, the end portion 220a of the second substrate 220 on which the second electrode terminal 223a is formed extends offset from the first substrate 210.

The first and second substrates 210 and 220 may be formed to have different lengths. For example, the second substrate 220 may be longer than the first substrate 210, and the end portion 220a of the second substrate 220 on the left side may extend offset from the first substrate 210. By forming the second electrode terminal 223a on the end portion 220a of the second substrate 220 on the left side to extend offset from the first substrate 210, physical interference may be reduced when coupling the first and second electrode terminals 210a and 220a.

Besides the second electrode terminal 223a coupled to the second electrode 223 and formed on the end portion 220a of the second substrate 220 on the left, a support (e.g., an isolation electrode) 225 that is separated from the second electrode 223 is formed on the end portion 220b of the second substrate 220 on the right side (e.g., opposite the end portion 220a). The support 225 is electrically insulated from the second electrode 223, and may be spatially separated from the second electrode 223 by, for example, a scribing gap SCR. After the second electrode terminal 223a and the support 225 are formed as a single unit with (e.g., integrally formed with) the second electrode 223, the support 225 may be separated from the second electrode 223 by laser scribing.

By separating the support 225 from the second electrode 223, an inner short circuit between the first electrode terminal 213a and the support 225 arranged in a vertical direction of the same cell S1 may be prevented, or at least the extent thereof may be reduced. For example, a positive-negative electrode short circuit is likely to occur in the first and second electrodes 213 and 223 of the same cell S1 due to the connector 250 that extends between the first electrode terminal 213a and the support 225.

As illustrated in FIG. 6, the connector 250 that extends between the first electrode terminal 213a of the cell S1 and the support 225 forms an electrical contact point with the second electrode terminal 223a of the cell S2, and thus, the cells S1 and S2 may be electrically coupled via the connector 250.

Although the connector 250 extends between the first electrode terminal 213a and the support 225 of the cell S1, it does not cause a short circuit between positive and negative electrodes due to the first electrode terminal 213a and the support 225. Although the first electrode terminal 213a is coupled to the first electrode 213, the support 225 is electrically insulated from the second electrode 223, and thus, a short circuit between the first and second electrodes 213 and 223 of the cell S1 is not caused.

Referring to FIG. 4, the cells S1, S2, S3, and S4 adjacent to one another are arranged in reversed/alternating patterns where positions of the first and second electrode terminals 213a and 223a thereof alternate (e.g., alternate between left and right). For example, the cells S1, S2, S3, and S4 are placed on the substrate 200 at a 180 degree difference from adjacent ones of the cells S1, S2, S3, and S4.

The first electrode terminal 213a of the cell S1 and the second electrode terminal 223a of the cell S2 are arranged adjacent to each other on the same side of the sealing member 230 (e.g., on the right side of the sealing member 230).

Similarly, the first electrode terminal 213a of the cell S2 and the second electrode terminal 223a of the cell S3 are arranged adjacent to each other on the same side of the sealing member 230 (e.g., on the left side of the sealing member 230).

Likewise, the first electrode terminal 213a of the cell S3 and the second electrode terminal 223a of the cell S4 are arranged adjacent to each other on the same side of the sealing member 230 (e.g., on the right side of the sealing member 230).

By arranging the first and second electrode terminals 213a and 223a of opposite polarities of the cells S1, S2, S3, and S4 to be adjacently coupled to one another on the left side or on the right side of the sealing member 230, the group of the cells S1, S2, S3, and S4 may be serially coupled. The first and second electrode terminals 213a and 223a of the cells S1, S2, S3, and S4 adjacent to one another may be electrically coupled to each other via the connector 250. In the present embodiment, the connectors 250 may be alternately formed on the left and on the right sides of the sealing member 230 along the arrangement direction of the cells S1, S2, S3, and S4 to electrically couple the respective pairs of adjacent ones of the cells S1, S2, S3, and S4.

The connector 250 may be formed of various materials having electrical conductivity, and may be formed of a metal having a high conductivity, such as copper.

For example, the connector 250 may be formed of a rod member that extends along a direction (e.g., a predetermined direction). For example, a connector (e.g., a connection member) 250 having a shape of a rod member may extend along the arrangement direction of cells and may couple adjacent first and second electrode terminals 213a and 223a to each other. For example, the connectors 250 between the first electrode terminals 213a and the supports 250 of the same cells extend between the adjacent ones of the cells S1, S2, S3, and S4, and form an electrical contact point with the second electrode terminals 223a of the adjacent cells S1, S2, S3, and S4.

For example, the connector 250 extends between the first electrode terminal 213a and the support 225 of the cell S1, and may form an electrical contact with the second electrode terminal 223a of the adjacent cell S2. Also, another connector 250 extends between the first electrode terminal 213a and the support 225 of the cell S2, and may form an electrical contact with the second electrode terminal 223a of the cell S3.

As described above, even when the connectors 250 extend between the first electrode terminals 213a and the supports 225 of the same cells, an inner short circuit therebetween is not generated, because, although the connector 250 is coupled to the first electrode 213 via the first electrode terminal 213a, the connector 250 is not coupled to the second electrode 223 via the support 225. As described above, the support 225 is separated from, and insulated from, the second electrode 223.

The connectors 250 between respective ones of the cells S1, S2, S3, and S4 is alternately arranged on the left and right sides of the photoelectric conversion module along an arrangement direction of the cells S1, S2, S3, and S4. For example, along the arrangement direction of the cells S1, S2, S3, and S4, the connector 250 between the cells S1 and S2 is formed on the right side of the photoelectric conversion module, and the connector 250 between the cells S2 and S3 is formed on the left side of the photoelectric conversion module. The connector 250 between the cells S3 and S4 is formed on the right side of the photoelectric module.

For example, the cells S1, S2, S3, and S4 that form the photoelectric conversion module may have a rectangular shape having a pair of long side portions and a pair of short side portions, and the connector 250 couples the short side portions of adjacent ones of the cells S1, S2, S3, and S4, that is, couples the first and second electrode terminals 213a and 223a formed as the short side portions of adjacent ones of the cells S1, S2, S3, and S4.

As described above, as the connector 250 electrically couples the short side portions of adjacent ones of the cells S1, S2, S3, and S4, dead areas of the photoelectric conversion module formed due to the connection structure, that is, dead areas which do not contribute to photoelectric conversion according to reception of incident light, may be reduced, and a light output efficiency with respect to a unit surface area may be increased.

For example, if the first and second electrode terminals 213a and 223a are formed as the long side portions of the cells S1, S2, S3, and S4, instead of being formed as the short side portions, and the connector 250 couples the long side portions of each of the cells S1, S2, S3, and S4, a surface area for a connection structure is increased along a length direction of the long side portions, and thus, dead areas of the photoelectric conversion module are increased.

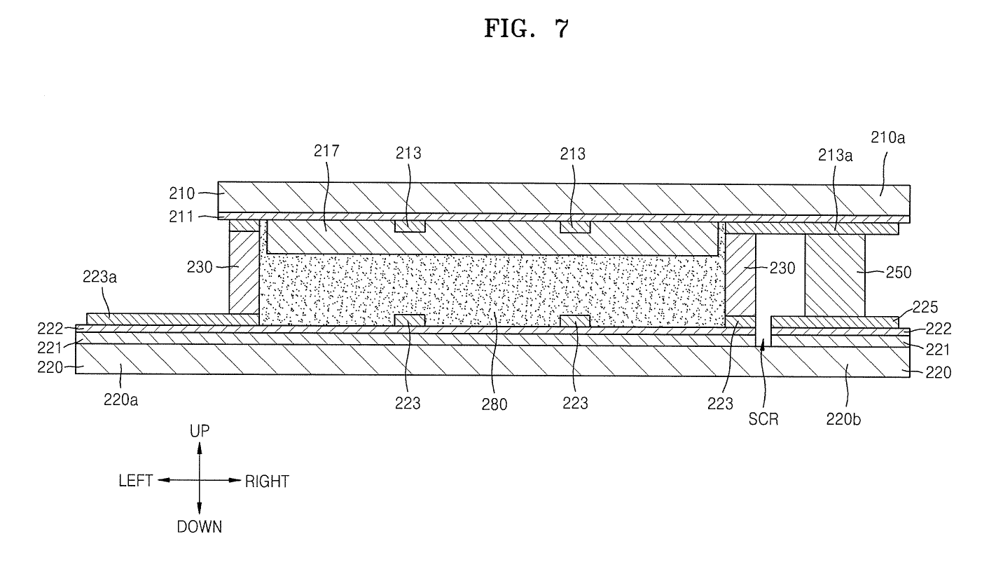

FIG. 7 is a cross-sectional view of the cell S1 of the photoelectric conversion module of the embodiment shown in FIG. 5 cut along a line VII-VII. The components of the cell S1 are described as follows in detail with reference to FIG. 7.

The first and second substrates 210 and 220 may be formed of a transparent material having a high light transmitting rate. For example, the first and second substrates 210 and 220 may be formed of a glass substrate or a resin film. A resin film usually has flexibility, and thus, is appropriate for use where flexibility is required.

First and second conductive layers 211 and 221 formed on the first and second substrates 210 and 220, respectively, may be formed of a transparent conductive material having electrical conductivity and optical transparency. For example, the first and second conductive layers 211 and 221 may be formed of a TCO, such as ITO, FTO, or ATO.

The first and second electrodes 213 and 223 formed on the first and second substrates 210 and 220, respectively, may be formed of an opaque metal having a high electrical conductivity, such as Al or Ag.

Although not shown in FIG. 7, a protection layer may be formed on surfaces of the first and second electrodes 213 and 223. The protection layer reduces or prevents corrosion of the first and second electrodes 213 and 223, and may be formed of a material that does not react with an electrolyte 280. For example, the protection layer may be formed of a glass frit.

A light-absorbing layer 217 may be formed adjacent to the first electrode 213. For example, the light-absorbing layer 217 may be formed on the first electrode 213, and may include a semiconductor layer and a photosensitive dye that is adsorbed on the semiconductor layer. For example, the semiconductor layer may be formed of a metal oxide of Cd, Zn, In, Pb, Mo, W, Sb, Ti, Ag, Mn, Sn, Zr, Sr, Ga, Si, and/or Cr.

For example, the photosensitive dye adsorbed in the semiconductor layer absorbs a visible light band, and may be formed of molecules that cause quick electron transfer from a light excitation state to the semiconductor layer. For example, a ruthenium-based dye may be used as the photosensitive dye.

A reduction catalyst layer 222 may be formed between the second substrate 220 and the second electrode 223. The reduction catalyst layer 222 may be formed of a material that has a reduction-catalyzing function and provides electrons to the electrolyte 280. The reduction catalyst layer 222 may be formed of a metal such as, for example, platinum (Pt), gold (Au), silver (Ag), copper (Cu), aluminum (Al), a metal oxide such as tin oxide, or a carbonaceous material such as graphite. The electrolyte 280 between the light-absorbing layer 217 and the reduction catalyst layer 222 may include a Redox electrolyte including a pair of an oxidant and a reducing agent.

The first and second electrodes 213 and 223 including the first and second electrode terminals 213a and 223a extend to the outside of the sealing member 230 (e.g., beyond an edge of a profile of the sealing member 230), and the first and second electrode terminals 213a and 223a may be formed on opposite (e.g., left and right) sides of the sealing member 230.

For example, the end portion 220a of the second substrate 220 on the left side on which the second electrode terminal 223a is formed may extend offset from the first substrate 210 of the same cell, and by forming the second electrode terminal 223a on the end portion 220a of the second substrate 220 on the left, physical interference due to the first substrate 210 may be reduced when coupling the first and second electrode terminals 210a and 220a.

For example, the support 225 that is separated from the second electrode 223 is formed on the end portion 220b of the second substrate 220 on the right. The support 225 may be electrically insulated via the scribing gap SCR from the second electrode 223, as well as the reduction catalyst layer 222 and the second conductive layer 221 that are electrically coupled to the second electrode 223. For example, the second conductive layer 221, the reduction catalyst layer 222, and the second electrode 223 may be formed on the second substrate 220 at the same time, and then a scribing gap SCR may be formed to remove portions corresponding to the scribing gap SCR by laser scribing, thereby forming the support 225 that is electrically insulated from the second electrode 223. Accordingly, a short circuit between positive and negative electrodes due to the connector 250 extended via the first electrode terminal 213a and the support 225 is not generated.

It should be understood that the exemplary embodiments described herein should be considered in a descriptive sense only and not for purposes of limitation. Descriptions of features or aspects within each embodiment should typically be considered as available for other similar features or aspects in other embodiments.

While this disclosure has been described in connection with what is presently considered to be practical exemplary embodiments, it is to be understood that the present invention is not limited to the disclosed embodiments, but, on the contrary, is intended to cover various modifications and equivalent arrangements included within the spirit and scope of the appended claims and their equivalents.

### DESCRIPTION OF SOME OF THE REFERENCE CHARACTERS

| | |
|---|---|
| 100, 200: support substrate | 110, 210: first substrate |
| 110a, 210a: end portion of the first | 111, 211: first conductive layer |
| substrate | |
| 113, 213: first electrode | 113a, 213a: first electrode |
| | terminal |
| 117, 217: light-absorbing layer | 120, 220: second substrate |
| 120a, 220a, 220b: end portion of the | 121, 221: second conductive |
| second substrate | layer |
| 122, 222: reduction catalyst layer | 123, 223: second electrode |
| 123a, 223a: second electrode terminal | 130, 230: sealing member |
| 150, 250: connector/connection member | 180, 280: electrolyte |
| 225: support/isolation electrode | SCR: scribing gap |

What is claimed is:

1. A photoelectric conversion module comprising:
a plurality of electrically coupled cells, each comprising:
a first substrate on which a first electrode is located;
a second substrate on which a second electrode is located; and
a sealing member between the first and second substrates; and
first and second electrode terminals respectively extending from the first and second electrodes to beyond edges of the sealing member on opposite sides of the sealing member,
wherein positions of the first and second electrode terminals of adjacent ones of the cells are respectively different.

2. The photoelectric conversion module of claim 1, wherein the first electrode terminal of a first cell of the plurality of cells and the second electrode terminal of a second cell that is adjacent to the first cell from among the plurality of cells are on a same side with respect to the sealing member.

3. The photoelectric conversion module of claim 2, further comprising a connector electrically coupling the first electrode terminal of the first cell to the second electrode terminal of the second cell.

4. The photoelectric conversion module of claim 3, further comprising a plurality of connectors to respectively electrically couple different pairs of the cells.

5. The photoelectric conversion module of claim 3, wherein the first electrode terminal of the first cell and the second electrode terminal of the second cell are offset in a direction perpendicular to the substrate.

6. The photoelectric conversion module of claim 3, wherein the connector comprises a flexible material.

7. The photoelectric conversion module of claim 3, wherein the connector extends along an arrangement direction of the plurality of cells.

8. The photoelectric conversion module of claim 7, wherein the connector extends from between the first electrode terminal and a support of the first cell to the second electrode terminal of the second cell.

9. The photoelectric conversion module of claim 8, wherein the connector is bar-shaped or rod-shaped,
wherein a lower end of the connector contacts the support of the first cell and the second electrode terminal of the second cell, and
wherein an upper end of the connector contacts the first electrode terminal of the first cell.

10. The photoelectric conversion module of claim 8, wherein the support of the first cell is electrically insulated from the second electrode of the first cell.

11. The photoelectric conversion module of claim 10, wherein the support comprises a same material as a material of the second electrode of the first cell and is spatially separated from the second electrode.

12. The photoelectric conversion module of claim 1, wherein each of the plurality of cells has a substantially rectangular shape, and
wherein the first and second electrode terminals of respective ones of the plurality of cells are formed at adjacent short sides of the cells.

13. The photoelectric conversion module of claim 1, wherein the first and second electrode terminals are formed on first end portions of the first and second substrates, respectively.

14. The photoelectric conversion module of claim 13, wherein the first end portions of the first and second substrates extend beyond respective edges of the sealing member on opposite sides of the sealing member.

15. The photoelectric conversion module of claim 14, wherein the first and second substrates are coupled to face each other, and are offset with respect to each other in a direction perpendicular to an arrangement direction of the cells, and
wherein the first end portions of the first and second substrates are each respectively offset with respect to an opposite substrate of the first and second substrates in the direction perpendicular to the arrangement direction of the cells.

16. The photoelectric conversion module of claim 13, wherein the first end portion of the second substrate is offset from the first substrate in a direction perpendicular to an arrangement direction of the cells.

17. The photoelectric conversion module of claim 16, wherein the second substrate further comprises a second end portion on a side of the second substrate that is opposite to the first end portion of the second substrate, and
wherein a support of the second substrate is electrically insulated from the second electrode of the second substrate and is located on the second end portion of the second substrate.

18. The photoelectric conversion module of claim 17, wherein the second substrate is longer than the first substrate.

19. The photoelectric conversion module of claim 1, further comprising an electrolyte-filled space enclosed by the first and second substrates and the sealing member.

20. The photoelectric conversion module of claim 1, wherein the first electrode terminal is integrally formed with the first electrode, and
wherein the second electrode terminal is integrally formed with the second electrode.
